(19) United States
(12) Patent Application Publication
(10) Pub. No.: US 2022/0286126 A1
(43) Pub. Date: Sep. 8, 2022

(54) OUTPUT DEVICE

(71) Applicants: AutoNetworks Technologies, Ltd., Yokkaich-shi, Mie (JP); Sumitomo Wiring Systems, Ltd., Yokkaichi, Mie (JP); Sumitomo Electric Industries, Ltd., Osaka-shi, Osaka (JP)

(72) Inventors: Keisuke WAKAZONO, Yokkaich-shi, Mie (JP); Sigeyuki FUJII, Yokkaich-shi, Mie (JP); Yuuki SUGISAWA, Yokkaich-shi, Mie (JP)

(21) Appl. No.: 17/753,033

(22) PCT Filed: Aug. 3, 2020
(86) PCT No.: PCT/JP2020/029709

§ 371 Date: Feb. 16, 2022

(30) Foreign Application Priority Data
Aug. 22, 2019 (JP) 2019-151933

(51) Int. Cl. H03K 17/687; H03K 17/74; H03K 17/06; H03K 17/14; H02J 7/00

(52) U.S. Cl. CPC H03K 17/687; H03K 17/74; H03K 17/063; H03K 17/14; H02J 7/0063

(57) ABSTRACT

An output device outputs a current through a semiconductor switch. With regard to the semiconductor switch, a resistance value between a current receiving terminal for receiving a current and a current output terminal for outputting a current decreases as the voltage at a control terminal rises. A first diode is disposed in a first path extending from the current receiving terminal to the control terminal. The voltage at the current receiving terminal is applied to the control terminal of the semiconductor switch via the first diode. A booster circuit is disposed in a second path extending from the current receiving terminal to the control terminal. The booster circuit boosts the voltage that is received from the current receiving terminal, and applies the boosted voltage to the control terminal.

### CROSS-REFERENCE TO RELATED APPLICATIONS

This application is the U.S. national stage of PCT/JP2020/029709 filed on Aug. 3, 2020, which claims priority of Japanese Patent Application No. JP 2019-151933 filed on Aug. 22, 2019, the contents of which are incorporated herein.

### TECHNICAL FIELD

The present disclosure relates to an output device.

### BACKGROUND

JP 2017-175808A discloses an output device that includes a semiconductor switch and outputs a current to a load from a battery through the semiconductor switch. The semiconductor switch is an N-channel FET (Field Effect Transistor). The battery applies voltage to the drain of the semiconductor switch. The current is input from the battery to the drain of the semiconductor switch, and is output from the source of the semiconductor switch to a load. Abooster circuit is arranged in a path extending from the drain to the gate, boosts the voltage that is received from the drain side, and applies the boosted voltage to the gate of the semiconductor switch. This raises the voltage at the gate of the semiconductor switch, and the resistance value between the drain and the source of the semiconductor switch decreases. As a result, the semiconductor switch is switched from OFF to ON, and a current is output to a load through the semiconductor switch.

In a conventional output device such as that described in JP 2017-175808A, a battery applies voltage to the drain of a semiconductor switch, and a booster circuit then raises the voltage at the gate of the semiconductor switch. As one configuration of a conventional output device, the battery applies voltage to the drain of the semiconductor switch, and the voltage that is input into the booster circuit gradually rises. With this configuration, the voltage that is output from the booster circuit rises from zero V.

Assume that one end of a load is connected to the source of the semiconductor switch, and the other end of the load is connected to a grounded capacitor, and when a voltage is applied to the drain of the semiconductor switch, the power stored in the capacitor is zero.

In this case, because the voltage that is output by the booster circuit is low for a while after the voltage at the gate of the semiconductor switch starts to rise, the resistance value between the drain and the source of the semiconductor switch is large. At this time, because almost no power is stored in the capacitor, a large current flows through the semiconductor switch. The larger the resistance value between the drain and the source of the semiconductor switch is, the larger the amount of heat generated in the semiconductor switch is. The larger the value of the current flowing through the semiconductor switch is, the larger the amount of heat generated in the semiconductor switch is. Therefore, the temperature of the semiconductor switch rapidly rises while the resistance value between the drain and the source of the semiconductor switch is large. If the resistance value between the drain and the source of the semiconductor switch is large for a long period of time, the temperature of the semiconductor switch may rise to an abnormal temperature, and the semiconductor switch may become damaged.

In view of this, an object of the present invention is to provide an output device in which the resistance value of a semiconductor switch is large for only a short period of time.

### SUMMARY

An output device according to an aspect of this disclosure is configured to output a current through a semiconductor switch whose resistance value between a current receiving terminal for receiving a current and a current output terminal for outputting a current decreases as a voltage at a control terminal rises. The output device includes a diode that is disposed in a first path extending from the current receiving terminal to the control terminal; and a booster circuit that is disposed in a second path extending from the current receiving terminal to the control terminal, and that is configured to boost a voltage that is received from the current receiving terminal side and to apply the boosted voltage to the control terminal. The voltage at the current receiving terminal is applied to the control terminal via the diode.

### Advantageous Effects of the Present Disclosure

According to this disclosure, the resistance value of the semiconductor switch is large for only a short period of time.

### BRIEF DESCRIPTION OF DRAWINGS

FIG. 1 is a circuit diagram of a power source system in this embodiment.

FIG. 2 is a graph showing behavior of a gate voltage.

FIG. 3 is a diagram illustrating the operation of an output device.

FIG. 4 is a diagram illustrating the operation when a first diode is not provided.

### DETAILED DESCRIPTION OF PREFERRED EMBODIMENTS

First, embodiments of the present disclosure will be listed and described. At least parts of the embodiments described below may also be freely combined.

An output device according to an aspect of this disclosure is configured to output a current through a semiconductor switch whose resistance value between a current receiving terminal for receiving a current and a current output terminal for outputting a current decreases as a voltage at a control terminal rises. The output device includes a diode that is disposed in a first path extending from the current receiving terminal to the control terminal; and a booster circuit that is disposed in a second path extending from the current receiving terminal to the control terminal, and that is configured to boost a voltage that is received from the current receiving terminal side and to apply the boosted voltage to the control terminal. The voltage at the current receiving terminal is applied to the control terminal via the diode.

With this aspect, while the voltage that the booster circuit applies to the control terminal of the semiconductor switch is lower than the voltage at the current receiving terminal, the voltage at the current receiving terminal is applied to the control terminal of the semiconductor switch via the diode. Therefore, the period of time for which the voltage that is applied to the control terminal of the semiconductor switch is lower than the voltage at the current receiving terminal, that is, the period of time for which the resistance value between the current receiving terminal and the current output terminal of the semiconductor switch is large, is short.

The output device according to an aspect of this disclosure is configured to output a current to a capacitor through the semiconductor switch.

With this aspect, the current is output to the capacitor through the semiconductor switch. With this configuration, while the voltage that the booster circuit applies to the control terminal of the semiconductor switch is lower than the voltage at the current receiving terminal, the value of the current flowing through the semiconductor switch is further increased, and the speed at which the temperature of the semiconductor switch rises is further increased. Therefore, with the configuration in which a current is output to the capacitor through the semiconductor switch, a large effect can be obtained by disposing a diode in the first path.

The output device according to an aspect of this disclosure includes a second diode disposed in the second path and a second capacitor whose one end is connected to a connection node between the second diode and the booster circuit and to which the voltage at the current receiving terminal is applied via the second diode, in which a voltage at the second capacitor is input into the booster circuit, and the booster circuit is configured to boost the voltage that is input into it, if the input voltage is at least a voltage threshold.

With the above-described aspect, because the second capacitor is disposed, even if the voltage at the current receiving terminal of the semiconductor switch decreases to a voltage of less than the voltage threshold, the voltage that is input into the booster circuit is maintained at at least the voltage threshold, and the booster circuit is unlikely to stop boosting the voltage. With this configuration, the voltage that is input into the booster circuit, that is, the voltage between two ends of the second capacitor, gradually rises after a voltage is applied to the current receiving terminal of the semiconductor switch. Therefore, the booster circuit raises the voltage that is output to the gate of the semiconductor switch 20 from zero V. Thus, a large effect can be obtained by disposing the diode in the first path.

Specific examples of a power source system according to embodiments of the present disclosure will be described hereinafter with reference to the drawings. Note that the present invention is not limited to the illustrations, but rather is indicated by the claims. All modifications within the meaning and range of equivalence to the claims are intended to be encompassed therein.

### Configuration of Power Source System

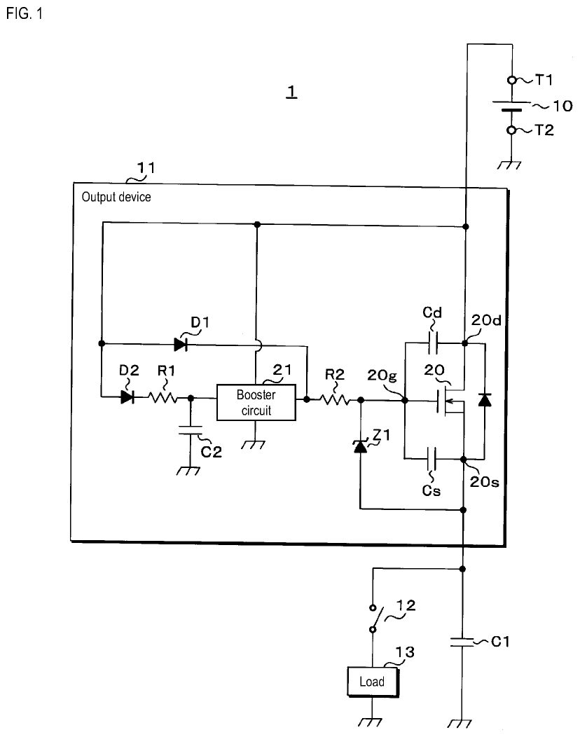

FIG. 1 is a circuit diagram of a power source system 1 in this embodiment. The power source system 1 is suitably installed in a vehicle. The power source system 1 includes a battery 10, an output device 11, a load switch 12, a load 13, a capacitor C1, a positive terminal T1, and a negative terminal T2. The battery 10 is connected by a user to the positive terminal T1 and to the negative terminal T2, for example. Specifically, the positive electrode and the negative electrode of the battery 10 are respectively connected to the positive terminal T1 and to the negative terminal T2. The positive terminal T1 is connected to the output device 11. The negative terminal T2 is grounded.

The output device 11 is further connected to one end of the load switch 12 and to one end of the capacitor C1. The other end of the load switch 12 is connected to one end of the load 13. The other end of the load 13 and the other end of the capacitor C1 are grounded.

If the battery 10 is connected to the positive terminal T1 and to the negative terminal T2, and when the voltage between the positive terminal T1 and the negative terminal T2 is at least a voltage threshold, the output device 11 outputs a current to the capacitor C1, and the capacitor C1 is charged. The voltage threshold has a constant value, and is preset. If the load switch 12 is ON, the battery 10 supplies power to the load 13 via the output device 11, or the capacitor C1 supplies the stored power to the load 13. The load 13 is an electrical apparatus that is installed in a vehicle.

The load switch 12 is switched ON or OFF by a switching circuit (not shown). If the switching circuit switches the load switch 12 from OFF to ON, power is supplied to the load 13, and the load 13 operates. If the switching circuit switches the load switch 12 from ON to OFF, the supply of power to the load 13 is stopped, and the load 13 stops operating.

Hereinafter, the voltage at the positive electrode of the battery 10 with respect to the ground potential will be referred to as “battery voltage”. The battery voltage changes due to various factors. The capacitor C1 smooths the battery voltage. Therefore, even if the battery voltage changes, a stable voltage is applied to the load 13.

If the voltage between the positive terminal T1 and the negative terminal T2 is less than the voltage threshold, for example, if an inappropriate DC power source that outputs a low voltage as the battery 10 is connected to the positive terminal T1 and the negative terminal T2, the output device 11 does not output a current to the load 13 or the capacitor C1.

Configuration of Output Device 11

The output device 11 includes a semiconductor switch 20, a booster circuit 21, capacitors C2, Cd, and Cs, a first diode D1, a second diode D2, resistors R1 and R2, and a Zener diode Z1. The semiconductor switch 20 is an N-channel FET. The capacitor Cd is connected to the drain 20d and to the gate 20g of the semiconductor switch 20. The capacitor Cs is connected to the source 20s and to the gate 20g of the semiconductor switch 20. The capacitors Cd and Cs are parasitic capacitances formed when the semiconductor switch 20 is manufactured.

The drain 20d of the semiconductor switch 20 is connected to the positive terminal T1, and its source 20s is connected to one end of the load switch 12 and to one end of the capacitor C1. The booster circuit 21 and the anodes of the first diode D1 and the second diode D2 are also connected to the drain 20d. The cathode of the second diode is connected to one end of the resistor R1. The other end of the resistor R1 is connected to the booster circuit 21 and to one end of the capacitor C2. The other end of the capacitor C2 is grounded.

As described above, one end of the capacitor C2 is connected to a connection node between the booster circuit 21 and the second diode D2.

The cathode of the first diode D1 is connected to the booster circuit 21 and to one end of the resistor R2. The booster circuit 21 is grounded. The other end of the resistor R2 is connected to the gate 20g of the semiconductor switch 20 and to the cathode of the Zener diode Z1. The anode of the Zener diode Z1 is connected to the source 20s of the semiconductor switch 20.

Hereinafter, the resistance value between the drain 20d and the source 20s of the semiconductor switch 20 will be referred to as “switch resistance value”. The voltage at the gate 20g of the semiconductor switch 20 with respect to the ground potential will be referred to as “gate voltage”. If the gate voltage of the semiconductor switch 20 rises, the switch resistance value decreases. If the gate voltage is sufficiently high, the switch resistance value is sufficiently small, and thus the semiconductor switch 20 is ON. If the gate voltage is sufficiently low, the switch resistance value is sufficiently large, and thus the semiconductor switch 20 is OFF.

If the semiconductor switch 20 is ON, a current is output from the battery 10 to the capacitor C1 through the semiconductor switch 20. If the semiconductor switch 20 is ON, when the load switch 12 is ON, a current is output from the battery 10 to the load 13 through the semiconductor switch 20. If a current is output through the semiconductor switch 20, the current is input from the positive electrode of the battery 10 to the drain 20d of the semiconductor switch 20, and the current is output from the source 20s of the semiconductor switch 20 to one or both of the load switch 12 and the capacitor C1. As described above, the switch resistance value decreases as the gate voltage rises. The drain 20d, the source 20s, and the gate 20g of the semiconductor switch 20 respectively function as a current receiving terminal, a current output terminal, and a control terminal.

If the battery 10 is connected to the positive terminal T1 and to the negative terminal T2, the voltage at the drain 20d of the semiconductor switch 20 with respect to the ground potential, that is, the battery voltage, is applied to the gate 20g of the semiconductor switch 20 via the first diode D1 and the resistor R2. Accordingly, one or both of the capacitors Cd and Cs are charged, and the gate voltage rises.

Also, if the battery 10 is connected to the positive terminal T1 and to the negative terminal T2, the battery 10 supplies power to the booster circuit 21, and the booster circuit 21 operates. Furthermore, the current flows from the positive electrode of the battery 10 to the second diode D2, the resistor R1, and the capacitor C2 in the stated order, and the voltage at the drain 20d of the semiconductor switch 20 with respect to the ground potential, that is, the battery voltage, is applied to the capacitor C2 via the second diode D2. Accordingly, the capacitor C2 is charged, and the voltage between the two ends of the capacitor C2 rises. The voltage between two ends of the capacitor C2 is input into the booster circuit 21 from the drain 20d side of the semiconductor switch 20. The capacitor C2 functions as a second capacitor.

If the voltage that is received from the drain 20d side of the semiconductor switch 20, that is, the voltage between the two ends of the capacitor C2, is at least a voltage threshold, the booster circuit 21 boosts the voltage that is received from the drain 20d side of the semiconductor switch 20 and applies the boosted voltage to the gate 20g of the semiconductor switch 20 via the resistor R2. Accordingly, one or both of the capacitors Cd and Cs are charged, and the gate voltage rises. The booster circuit 21 raises the voltage that is output to the gate 20g of the semiconductor switch 20 from zero V to a preset target voltage. If the gate voltage is the target voltage, the gate voltage is sufficiently high, and the semiconductor switch 20 is ON. The booster circuit 21 raises the gate voltage by boosting the voltage and switches the semiconductor switch 20 from OFF to ON.

If the input voltage, that is, the voltage between two ends of the capacitor C2, is less than the voltage threshold, the booster circuit 21 does not boost the input voltage or apply voltage to the gate 20g of the semiconductor switch 20. At this time, the gate voltage is sufficiently low, and the semiconductor switch 20 is OFF.

Based on the above, the following can be stated for the output device 11. No power is stored in the capacitors Cd or Cs before the output device 11 is shipped out. If the voltage between the positive terminal T1 and the negative terminal T2 is less than the voltage threshold in a state where no power is stored in the capacitors Cd or Cs, the semiconductor switch 20 is kept OFF, and the output device 11 does not output a current. If the voltage between the positive terminal T1 and the negative terminal T2 is at least the voltage threshold, that is, if an appropriate battery 10 is connected to the positive terminal T1 and to the negative terminal T2, the semiconductor switch 20 is switched ON, and the output device 11 outputs a current.

Note that a decrease in the voltage at the second diode D2 is ignored. If a decrease in voltage is not ignored, the voltage threshold relating to the voltage between the positive terminal T1 and the negative terminal T2 is slightly higher than the voltage threshold relating to the voltage between the two ends of the capacitor C2.

As described above, after the battery 10 is connected to the positive terminal T1 and to the negative terminal T2, the battery voltage changes. The capacitor C2 smooths the battery voltage. Thus, even if the battery voltage has decreased to a voltage of less than the voltage threshold, the voltage between the two ends of the capacitor C2 is maintained at at least the voltage threshold, and the booster circuit 21 is unlikely to stop boosting the voltage.

A current flows through the cathode and the anode of the Zener diode Z1 in the stated order if the voltage at the gate 20g with respect to the potential of the source 20s of the semiconductor switch 20 reaches a breakdown voltage at the Zener diode Z1. This prevents the voltage at the gate 20g with respect to the potential of the source 20s from exceeding the breakdown voltage. If the voltage at the gate 20g with respect to the potential of the source 20s of the semiconductor switch 20 is less than the breakdown voltage, no current flows through the Zener diode Z1, and the voltage at the gate 20g with respect to the potential of the source 20s does not change due to the effect of the Zener diode Z1. The breakdown voltage is constant. The breakdown voltage is at least the target voltage.

As described above, with the output device 11, the battery voltage is applied to the gate 20g of the semiconductor switch 20 via the first diode D1, and the booster circuit 21 boosts the voltage between the two ends of the capacitor C2 and applies the boosted voltage to the gate 20g of the semiconductor switch 20. Thus, the output device 11 includes two paths for current flowing from the drain 20d to the gate 20g of the semiconductor switch 20. The first diode D1 and the resistor R2 are disposed in the first path for current flowing from the drain 20d of the semiconductor switch 20 to the gate 20g of the semiconductor switch 20. The second diode D2, the booster circuit 21, and the resistor R2 are disposed in the second path for current flowing from the drain 20d of the semiconductor switch 20 to the gate 20g of the semiconductor switch 20.

### Operation of Output Device 11

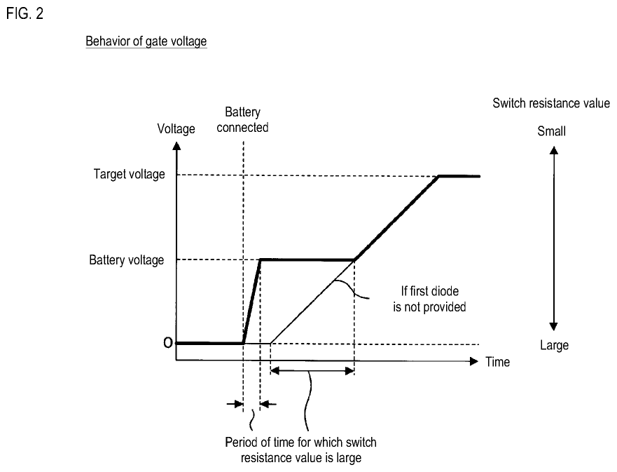

FIG. 2 is a graph showing the behavior of the gate voltage. A thick solid line indicates the behavior of the gate voltage in the output device 11 in FIG. 2. A thin solid line indicates the behavior of the gate voltage if the output device 11 does not include the first diode D1. An overlapping portion where two curves overlap each other is indicated by a thick solid line. As described above, the higher the gate voltage is, the smaller the switch resistance value is. The battery 10 is connected to the positive terminal T1 and to the negative terminal T2 in a state where the load switch 12 is OFF.

The behavior of the gate voltage in the output device 11 will be described below. If no power is stored in the capacitor C1 and the battery 10 is not connected to the positive terminal T1 or to the negative terminal T2, the gate voltage is zero V. If the battery 10 is connected to the positive terminal T1 and to the negative terminal T2, the battery voltage is applied to the gate 20g of the semiconductor switch 20 via the first diode D1 and the resistor R2, and one or both of the capacitors Cd and Cs are rapidly charged. As a result, the gate voltage immediately rises to the battery voltage.

If the battery 10 is connected to the positive terminal T1 and to the negative terminal T2 and the voltage between the two ends of the capacitor C2 reaches at least the voltage threshold, the booster circuit 21 boosts the voltage between the two ends of the capacitor C2 and raises the voltage that is output to the gate 20g of the semiconductor switch 20 from zero V. The gate voltage is maintained at the battery voltage while the voltage that is output to the gate 20g of the semiconductor switch 20 is not more than the battery voltage.

If the voltage that is output to the gate 20g of the semiconductor switch 20 exceeds the battery voltage, the gate voltage rises to the target voltage together with the voltage that is output by the booster circuit 21 to the gate 20g of the semiconductor switch 20. Because the voltage that is output by the booster circuit 21 to the gate 20g of the semiconductor switch 20 is then maintained at the target voltage, the gate voltage is also maintained at the target voltage. As described above, if the gate voltage is the target voltage, the semiconductor switch 20 is ON.

The following describes the behavior of the gate voltage if the output device 11 does not include the first diode D 1. If the output device 11 does not include the first diode D1, the gate voltage behaves in the same manner as the voltage that is output by the booster circuit 21 to the gate 20g of the semiconductor switch 20.

If no power is stored in the capacitor C1 and the battery 10 is not connected to the positive terminal T1 or to the negative terminal T2, the gate voltage is zero V. If the battery 10 is connected to the positive terminal T1 and to the negative terminal T2 and the voltage between the two ends of the capacitor C2 then reaches at least the voltage threshold, the booster circuit 21 boosts the voltage between the two ends of the capacitor C2 and raises the voltage that is output to the gate 20g of the semiconductor switch 20 from zero V. The gate voltage rises to the target voltage together with the voltage that is output by the booster circuit 21 to the gate 20g of the semiconductor switch 20.

If the behavior of the gate voltage in the output device 11 is compared to the behavior of the gate voltage when the first diode D1 is not provided in the output device 11, the period of time for which the gate voltage is less than the battery voltage, that is, the period of time for which the switch resistance value is large, is shorter with the output device 11.

If the gate voltage rises and the switch resistance value decreases, a current flows through the semiconductor switch 20. The battery voltage and the switch resistance value are respectively expressed by Vb and rs, and a capacitor voltage, which is the voltage between the two ends of the capacitor C1, is expressed by Vc. In this case, a switch current flowing through the semiconductor switch 20 is calculated by (Vb−Vc)/rs.

At a point of time when the battery 10 is connected to the positive terminal T1 and to the negative terminal T2, no power is stored in the capacitor C1, and the capacitor voltage Vc is zero V. Thus, immediately after the battery 10 is connected to the positive terminal T1 and to the negative terminal T2, a large switch current flows through the semiconductor switch 20 in a state where the switch resistance value is large.

If the switch current is expressed by Is, the larger the Ise rs is, the larger the amount of heat generated in the semiconductor switch 20 is. Therefore, immediately after the battery 10 is connected to the positive terminal T1 and to the negative terminal T2, a large amount of heat is generated in the semiconductor switch 20, and the temperature of the semiconductor switch 20 rapidly rises.

However, with the output device 11, the switch resistance value is large for a shorter period of time, and thus the temperature of the semiconductor switch 20 rapidly rises for only a short period of time, which prevents the temperature of the semiconductor switch 20 from rising to an abnormal temperature.

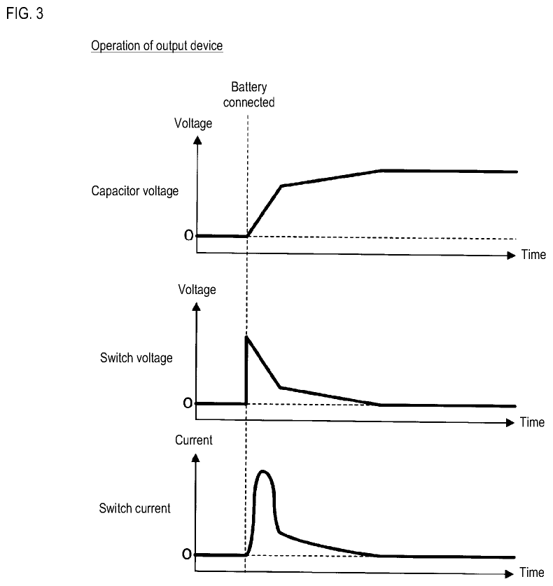

FIG. 3 is a diagram illustrating the operation of the output device 11. FIG. 3 shows the behavior of the capacitor voltage and the switch current. Furthermore, FIG. 3 shows the behavior of the switch voltage, which is the voltage between the drain 20d and the source 20s of the semiconductor switch 20. As described above, the battery 10 is connected to the positive terminal T1 and to the negative terminal T2 in a state where the load switch 12 is OFF.

At a point of time when the battery 10 is connected to the positive terminal T1 and to the negative terminal T2, the capacitor voltage is zero V and the switch voltage substantially coincides with the battery voltage. As described above, if the battery 10 is connected to the positive terminal T1 and to the negative terminal T2, the gate voltage rapidly rises to the battery voltage. As a result, the switch resistance value rapidly decreases, a large switch current flows to the capacitor C1, and the capacitor voltage rapidly rises.

The sum of the switch voltage and the capacitor voltage coincides with the battery voltage. Thus, if the capacitor voltage rapidly rises, the switch voltage rapidly decreases. The switch current rapidly decreases accompanying an increase in capacitor voltage. Thus, the switch current is large for a shorter period of time in a state where the switch voltage is large, that is, in a state where the switch resistance value is large.

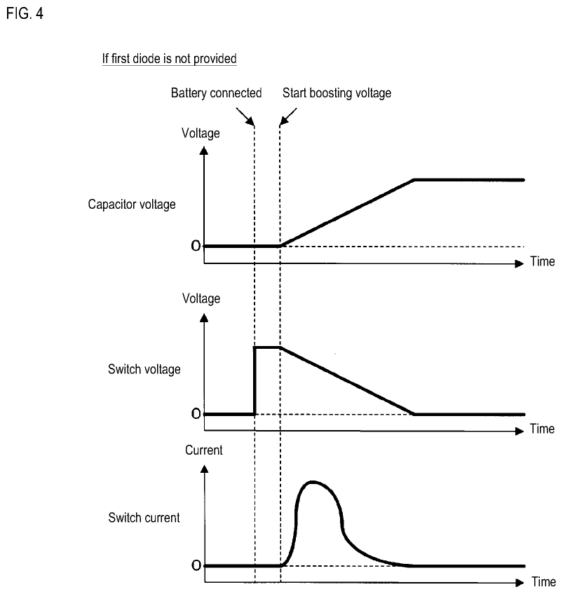

FIG. 4 is a diagram illustrating the operation when the first diode D1 is not provided. Similarly to FIG. 3, FIG. 4 shows the behaviors of the capacitor voltage, the switch voltage, and the switch current. The battery 10 is connected to the positive terminal T1 and to the negative terminal T2 in a state where the load switch 12 is OFF.

Because the booster circuit 21 does not output voltage from when the battery 10 is connected to the positive terminal T1 and to the negative terminal T2 to when the voltage between the two ends of the capacitor C2 is at least the voltage threshold, the capacitor voltage is zero V, and the switch voltage substantially coincides with the battery voltage. Because the semiconductor switch 20 is OFF, the switch current is zero A.

If the voltage between the two ends of the capacitor C2 is at least the voltage threshold, the booster circuit 21 starts boosting the voltage. The booster circuit 21 raises the voltage that is applied to the gate 20g of the semiconductor switch 20 to the target voltage. As a result, the gate voltage decreases. If the gate voltage decreases, the switch resistance value decreases, and a switch current starts to flow from the battery 10 to the capacitor C1 through the semiconductor switch 20.

At this time, the capacitor voltage is close to zero V, and thus, the switch current is large. Because the gate voltage slowly rises, the capacitor voltage slowly rises and the switch voltage slowly decreases. As a result, the switch current is large for a longer period of time in a state where the switch voltage is large, that is, in a state where the switch resistance value is large. In this case, the temperature of the semiconductor switch 20 rapidly rises for a long period of time. Thus, the temperature of the semiconductor switch 20 may rise to an abnormal temperature, and the semiconductor switch 20 may become damaged.

If the capacitor voltage reaches the battery voltage, that is, if the switch voltage reaches zero V, the switch current is zero A.

As described above, with the output device 11, the battery voltage is applied to the gate 20g of the semiconductor switch 20 via the first diode D1 while the voltage that is applied by the booster circuit 21 to the gate 20g of the semiconductor switch 20 is lower than the battery voltage. Therefore, the voltage that is applied to the gate 20g of the semiconductor switch 20 is lower than the battery voltage for only a short period of time, that is, the switch resistance value is large for only a short period of time.

Also, the current is output to the capacitor C1 through the semiconductor switch 20 of the output device 11 in the power source system 1. Therefore, the switch current is large and the temperature of the semiconductor switch 20 rapidly rises while the voltage that is applied by the booster circuit 21 to the gate 20g of the semiconductor switch 20 is lower than the battery voltage. Based on the above, in the power source system 1, a large effect can be obtained by disposing the first diode D1 in the output device 11. As described above, the structure in which the battery voltage is applied to the gate 20g of the semiconductor switch 20 is realized by disposing the first diode D1.

As described above, with the output device 11, if the voltage between the two ends of the capacitor C2 is at least the voltage threshold, the booster circuit 21 starts boosting the voltage between the two ends of the capacitor C2. With this configuration, the booster circuit 21 raises the voltage that is output to the gate 20g of the semiconductor switch 20 from zero V. Based on the above, a large effect can be obtained by disposing the first diode D1.

Note that it is sufficient that the semiconductor switch 20 is a semiconductor switch whose resistance value between the current receiving terminal for receiving a current and the current output terminal for outputting a current decreases as the voltage at the control terminal rises. Thus, the semiconductor switch 20 is not limited to an N-channel FET, and may also be an IGBT (Insulated Gate Bipolar Transistor), an NPN-bipolar transistor, or the like.

The embodiments disclosed herein are examples in all respects, and are not to be interpreted as restrictive. The scope of the present invention is defined not by the meanings of the foregoing descriptions but rather by the scope of the claims, and is intended to encompass all modifications within the meanings and scope that are equivalent to the claims.

1. An output device configured to output a current through a semiconductor switch whose resistance value between a current receiving terminal for receiving a current and a current output terminal for outputting a current decreases as a voltage at a control terminal rises, the output device comprising:
a diode that is disposed in a first path extending from the current receiving terminal to the control terminal;
a booster circuit that is disposed in a second path extending from the current receiving terminal to the control terminal, and that is configured to boost a voltage that is received from the current receiving terminal side and to apply the boosted voltage to the control terminal,
wherein the voltage at the current receiving terminal is applied to the control terminal via the diode.

2. The output device according to claim 1,
wherein a current is output to a capacitor through the semiconductor switch.

3. The output device according to claim 1, further comprising:
a second diode disposed in the second path; and
a second capacitor whose one end is connected to a connection node between the second diode and the booster circuit and to which the voltage at the current receiving terminal is applied via the second diode,
wherein a voltage at the second capacitor is input into the booster circuit, and
the booster circuit is configured to boost the voltage that is input into it, if the input voltage is at least a voltage threshold.

4. The output device according to claim 2, further comprising:
a second diode disposed in the second path; and
a second capacitor whose one end is connected to a connection node between the second diode and the booster circuit and to which the voltage at the current receiving terminal is applied via the second diode,
wherein a voltage at the second capacitor is input into the booster circuit, and
the booster circuit is configured to boost the voltage that is input into it, if the input voltage is at least a voltage threshold.
